(19) United States
(12) Patent Application Publication
(10) Pub. No.: US 2026/0280061 A1
(43) Pub. Date: Sep. 17, 2026

(54) BATTERY PACK

(71) Applicant: Panasonic Intellectual Property Management Co., Ltd., Osaka (JP)

(72) Inventor: AKIO TSUTSUI, Hyogo (JP)

(21) Appl. No.: 19/469,347

(22) PCT Filed: Apr. 3, 2024
(86) PCT No.: PCT/JP2024/013820

§ 371 Date: Sep. 25, 2025

(30) Foreign Application Priority Data
Apr. 17, 2023 (JP) 2023-066995

(51) Int. Cl. H01M 50/519; H01M 10/42; H01M 50/213; H01M 50/271; H01M 50/284; H01M 50/296; H05K 1/02

(52) U.S. Cl. CPC H01M 50/519; H01M 10/425; H01M 50/213; H01M 50/271; H01M 50/284; H01M 50/296; H05K 1/0298

(57) ABSTRACT

A battery block including a plurality of battery cells at predetermined positions, a circuit board connected to the battery cells of the battery block, and a lead plate connected to a lead connection part on a surface of the circuit board are included. The circuit board is a multilayer board including a plurality of insulating layers and wiring patterns, laminated in a plurality of layers. Furthermore, the circuit board includes a reflective copper foil reflecting a laser beam on a back surface of the first insulating layer including the lead connection part on the surface, facing a welded region in which the lead connection part and the lead plate are welded. A laser reflection surface of the reflective copper foil reflecting a laser beam on a surface adheres to a back surface of the insulating layer of the laminated structure, and is covered with an insulating layer.

### TECHNICAL FIELD

The present disclosure relates to a battery pack electrically connected to a circuit board by laser welding.

### BACKGROUND ART

In order to drive electrical equipment using a rechargeable secondary battery cell such as a lithium-ion secondary battery, a battery pack and a power supply device including a plurality of secondary battery cells are used in a variety of fields, as driving power sources for electric vehicles such as assist bicycles, electric carts, electric scooters, or as power sources for portable equipment such as electric tools and electric cleaners. Such battery packs and the like widely employ structures in which secondary battery cells are arranged at fixed positions in a battery holder, and a lead plate connected to electrodes of the secondary battery cells is exposed from the battery holder and electrically connected to a surface of the circuit board by soldering (for example, Patent Literature 1).

It is difficult to achieve always stable electrical connection by soldering. This is because a structure of electrically connecting a lead plate to a circuit board by soldering requires bringing a lead plate into contact with a lead connection part of the lead plate provided on the circuit board and keeping a contact state in which relative movement does not occur, melting solder in this state so that the molten solder adheres to both the lead connection part and the lead plate, and maintaining this state while the molten solder is cooled. It is difficult for soldering to achieve always stable electrical connection, by bringing molten solder into contact with the lead connection part and the surface of the lead plate and cooling in the contact state.

Soldering that always provides stable electrical connection needs the following requirements (1) to (3):
(1) keeping a contact state between a lead connection part and a lead plate,
(2) heating and melting solder in a contact position between the lead connection part and the lead plate or supplying the contact position with heated and molten solder so as to heat the lead connection part and the lead plate by the molten solder, raise a surface temperature of the heated lead connection part and the lead plate to a temperature higher than a melting temperature of the solder, and allowing the molten solder to flow onto surfaces of the lead connection part and the lead plate and adhere to each other; and
(3) furthermore, cooling the molten solder that adheres to the surfaces of the lead connection part and the lead plate without causing any positional displacement between the lead connection part and the lead plate.

Since stable soldering is achieved by satisfying the above requirements, it is necessary to keep the contact state in which the lead connection part and the lead plate are in contact with each other, raise surface temperatures of the lead connection part and the lead plate to be soldered to a temperature higher than the melting temperature of the solder, allow the solder to flow along surfaces of the lead connection part and adhere to each other, and further allow the molten solder to flow along surfaces of the lead connection part and the lead plate and keep the molten solder in a position where the lead connection part and the lead plate adhere to each other, and cool and harden the molten solder. In order to satisfy the requirement (1), the connection structure of Patent Literature 1 maintains the lead plate and the lead connection part of the circuit board to be soldered in an engaged state. This connection structure solders the lead pin and the lead plate in an engaged state with a lead pin bent into a unique shape. The above-mentioned laminated structure can link and solder the lead plate and the circuit board without causing any positional displacement, but this structure requires a lot of work for component processing and soldering because the lead pin is bent into a complicated shape, and the lead plate is engaged with the lead pin and soldered.

### Citation List

### Patent Literature

[PTL 1] Japanese Patent Application Unexamined Publication No. 2013-247100

### SUMMARY OF THE INVENTION

The connection structure of Patent Literature 1 allows the lead connection part and the lead plate to be arranged without any positional displacement, but electrical connection by soldering involves a problem that cannot be solved in principle. Since members to be connected are not directly connected to electrodes but are electrically connected via solder, the members may be mechanically linked but may not be electrically connected. The above problem can be solved by laser welding, instead of soldering, so as to melt both metals and make an electrical connection. However, because the laser welding melts both the lead connection part and the lead plate and electrically connects the lead connection part and the lead plate to each other, the laser beam that melts and links the both the lead connection part and the lead plate may melt the circuit board partially, causing disadvantages such as unintended short circuits, melting other members, and the like. The disadvantage that the laser beam penetrates the circuit board can be prevented by arranging a member that is not melted by the laser beam, for example, a member that blocks laser beams, such as a thick metal plate or ceramic, on a back surface of the circuit board, but this method requires a lot of work to arrange a member that blocks a laser beam at a laser beam penetration position, and furthermore, in a multilayer board, it is even more difficult to arrange a member that blocks a laser beam between the laminated insulating layers.

One of the objects of the present disclosure is to provide a battery pack that can reliably and stably connect electrodes of a circuit board and a lead plate, avoiding the disadvantage that a laser beam penetrates the circuit board without disposing a special-purpose member to solve the problem that the laser beam penetrates the circuit board.

A battery pack according to one embodiment of the present disclosure includes a battery block including a plurality of battery cells at fixed positions, a circuit board connected to the battery cells of the battery block, and a lead plate connected to a lead connection part provided on a surface of the circuit board. The circuit board is a multilayer board including a plurality of insulating layers and wiring patterns laminated in a plurality of layers. Furthermore, the circuit board includes a reflective copper foil reflecting a laser beam, on a back surface of the first insulating layer including a surface to which the lead connection part is disposed, and in a position facing a welded region in which the lead connection part and the lead plate are welded to each other. A laser reflection surface of the reflective copper foil, reflecting a laser beam on a surface, adheres to a back surface of any one of the insulating layers of a laminated structure, and the laser reflection surface is covered with the insulating layer.

The battery pack mentioned above is advantageous that the circuit board and the lead plate are laser welded and electrically connected to each other reliably and stably while a disadvantage that a laser beam penetrates the circuit board is avoided, without disposing a special-purpose member in order to solve a problem that a laser beam penetrates the circuit board.

### BRIEF DESCRIPTION OF THE DRAWINGS

FIG. 1 is a schematic perspective view of a battery pack according to one exemplary embodiment of the present disclosure.

FIG. 2 is a schematic exploded perspective view of the battery pack.

FIG. 3 is a schematic enlarged sectional view showing a laser welded region.

FIG. 4A is a schematic plan view showing a wiring pattern.

FIG. 4B is a schematic plan view showing the wiring pattern.

FIG. 5 is a schematic sectional view of a battery pack according to another exemplary embodiment of the present disclosure.

FIG. 6 is a schematic sectional view of a battery pack according to still another exemplary embodiment of the present disclosure.

### DESCRIPTION OF EMBODIMENT

The embodiments of the present disclosure may be characterized by the following configurations and characteristics.

A battery pack according to one aspect of the present disclosure includes a battery block including a plurality of battery cells at fixed positions, a circuit board connected to the battery cells of the battery block, and a lead plate connected to a lead connection part provided on a surface of the circuit board. The circuit board is a multilayer board including a plurality of insulating layers and wiring patterns laminated in a plurality of layers. Furthermore, the circuit board includes a reflective copper foil reflecting a laser beam on a back surface of the first insulating layer including a surface to which the lead connection part is disposed, and in a position facing a welded region in which the lead connection part and the lead plate are welded to each other. A laser reflection surface of the reflective copper foil, reflecting a laser beam on a surface, adheres to a back surface of any one of the insulating layers of a laminated structure, and the laser reflection surface is covered with the any insulating layer.

The battery pack mentioned above is advantageous that the circuit board and the lead plate are laser welded and electrically connected to each other reliably stably by avoiding a disadvantage that a laser beam penetrates the circuit board, without disposing a special-purpose member in order to solve a problem that a laser beam penetrates the circuit board. This is because the battery pack mentioned above includes a copper foil provided on the circuit board to which the lead plate is connected for use as a reflective copper foil that reflects a laser beam, and laser welds the lead connecting part and the lead plate. In this specification, the “lead plate” is not specified to a lead plate made entirely of a metal plate, but is used in a broad sense to include a lead wire with a plate-shaped connection terminal connected to the end part of the lead wire.

In a battery pack according to a second aspect, in the above embodiment, the multilayer board of the circuit board includes a second insulating layer laminated on a back surface of the first insulating layer, and the reflective copper foil can be placed between the first insulating layer and the second insulating layer. The above battery pack is advantageous that a laser beam penetrates only the first insulating layer provided with the lead connection part, and does not penetrate other insulating layers below the first insulating layer (the second insulating layer and other insulating layers below).

In a battery pack according to a third aspect of the present disclosure, in any one of the above embodiments, the reflective copper foil can be a floating island that is not connected to a copper foil of other wiring patterns. Since the above battery pack includes the reflective copper foil as a floating island, even when the laser beam melts the metal of the lead plate, the lead connection part, or the wiring pattern to be electrically connected to the reflective copper foil, no disadvantage caused by this electrical connection occurs.

In a battery pack according to a fourth aspect of the present disclosure, in any one of the above embodiments, the circuit board includes one or a plurality of the reflective copper foils, and at least one or more reflective copper foils can be made to be a floating island that is not connected to a copper foil of the other wiring pattern. The battery pack mentioned above can prevent the disadvantage that a laser beam penetrates the circuit board more reliably, and can improve safety by providing a plurality of reflective copper foils, and making one or more reflective copper foils be floating islands.

In a battery pack according to a fifth aspect of the present disclosure, in any one of the above embodiments, the lead connection part is fixed and electrically connected to a copper foil of a wiring pattern provided on a surface of the first insulating layer of the circuit board. Since the battery pack mentioned above provides a metal plate on a copper foil of the surface of the circuit board to make a lead connection part, the lead plate can stably electrically connect a lead plate to the circuit board via the metal plate.

In a battery pack according to a sixth aspect of the present disclosure, in any one of the above embodiments, the lead connection part can be a metal plate soldered to the copper foil of the wiring pattern. Since the battery pack mentioned above includes a lead connection part made by a metal plate soldered to the copper foil of the wiring pattern, the lead plate can be stably electrically connected to the circuit board via the metal plate.

In a battery pack according to a seventh aspect of the present disclosure, in any one of the above embodiments, a wiring pattern of a surface of the circuit board can include a copper foil removed region that does not include a copper foil of the wiring pattern directly below a welded region of the metal plate to which a lead connection part and a lead plate are melted. In the battery pack mentioned above, it is advantageous that when the wiring pattern (surface wiring pattern) on a surface of the circuit board includes a copper foil removed region that does not include a copper foil (surface copper foil) directly below the welded region, the copper foil (surface copper foil) is prevented from melting, and the melted copper foil (surface copper foil) is prevented from flowing down into a through hole, and thereby electric connection to the back surface of the insulating layer can be avoided.

In a battery pack according to an eighth aspect of the present disclosure, in any one of the above embodiments, the metal plate of the lead connection part is a metal plate that is thicker than the copper foil of the wiring pattern. In the above battery pack, since the lead plate can be connected to a circuit board via the metal plate thicker than the copper foil, it is advantageous that the lead plate and the circuit board can be reliably connected.

In a battery pack according to a ninth aspect of the present disclosure, in any one of the above embodiments, the metal plate of the lead connection part is a metal plate with a surface plated with nickel.

In a battery pack according to a tenth aspect of the present disclosure, in any one of the above embodiments, the battery block includes a battery holder including the plurality of battery cells at fixed positions, the battery holder includes the circuit board at a fixed position, and the lead plate includes a first end laser-welded to the lead connection part, and a second end connected to the battery cells.

A battery pack according an eleventh aspect of the present disclosure, in any one of the above embodiments, includes an outer covering case housing the circuit board and the battery block. The outer covering case includes an output terminal, the lead plate includes a first end laser-welded to the lead connection part, and a second end connected to the output terminal.

Hereinafter, the embodiments of the present disclosure are described in detail based on the drawings. Note here that in the following description, terms indicating specific directions and positions (for example, “upper”, “lower”, and other terms including these terms) are used as necessary. However, these terms are used to facilitate understanding of the invention with reference to the drawings, and the technical scope of the present disclosure is not limited by the meaning of these terms. Furthermore, parts or members with the same reference numerals in a plurality of drawings indicate the same or equivalent parts or members.

Furthermore, the exemplary embodiments described below are specific examples of the technical idea of the present disclosure, and the present disclosure is not limited to the following exemplary embodiments. The dimensions, materials, shapes, relative arrangements, and the like, of the components described below are not intended to limit the scope of the present disclosure only thereto but are intended to show examples, unless specifically stated. The contents described in relation to one exemplary embodiment and Example can be applied to other exemplary embodiments and Examples. The sizes and positional relationships of members shown in the drawings may be exaggerated in order to clarify the explanation.

Battery pack 100 of the present disclosure can be used for a structure in which lead plate 3 is laser welded and electrically connected to circuit board 2 connected to secondary battery cells 1. In particular, battery pack 100 of the present disclosure can be used for battery pack 100 including a plurality of secondary battery cells 1 at fixed positions by battery holder 12 to form battery block 10, circuit board 2 is connected to battery block 10, and lead plate 3 is laser welded to circuit board 2.

### First Exemplary Embodiment

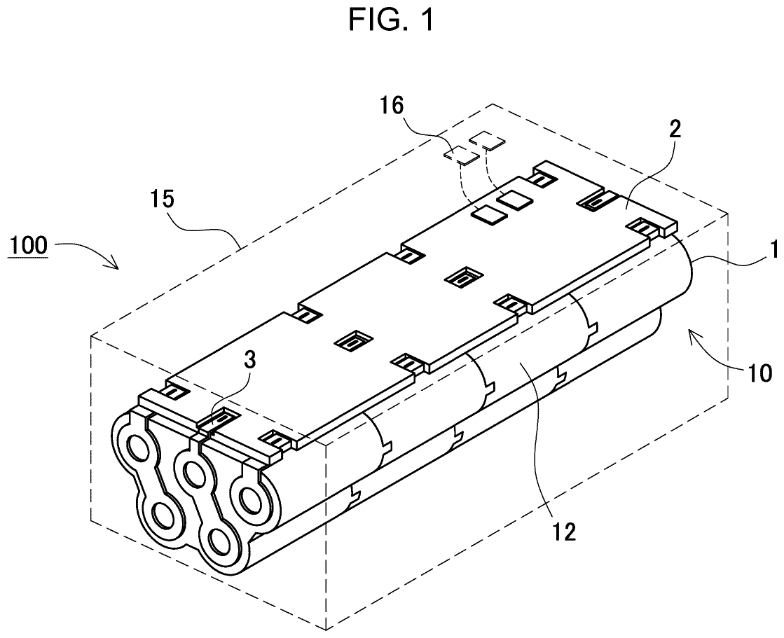

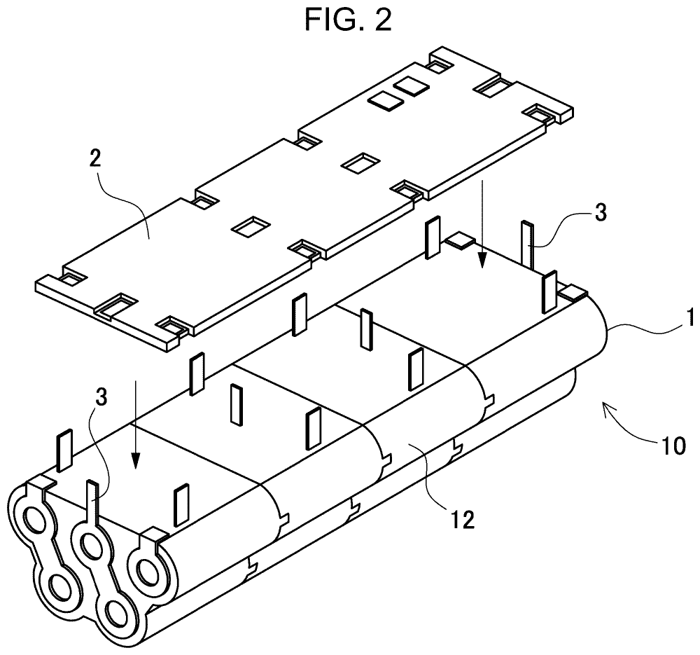

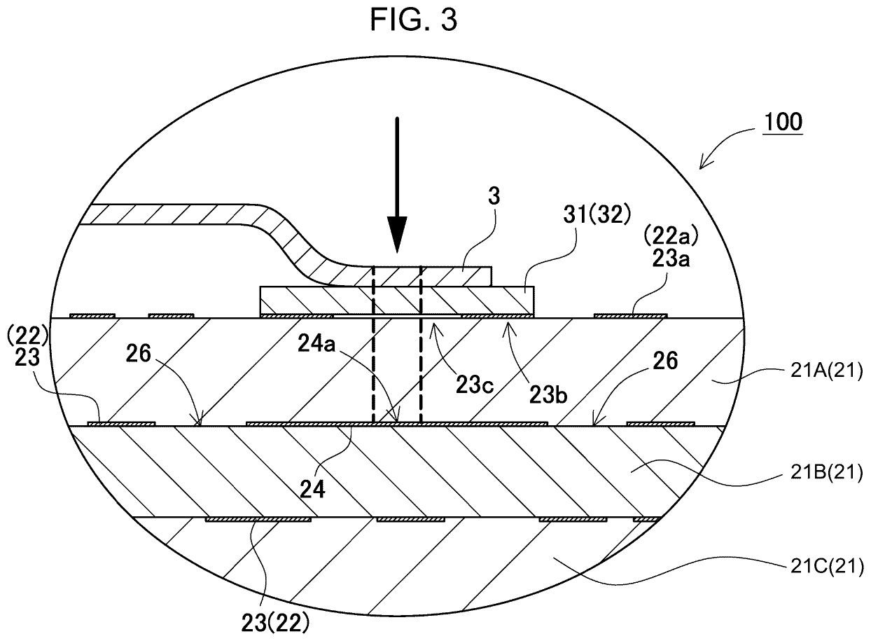

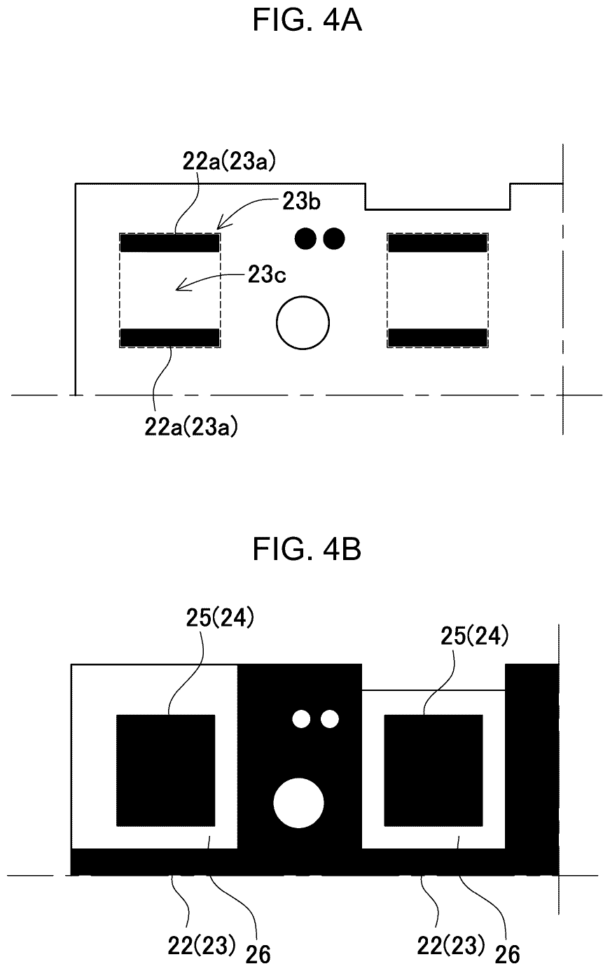

Battery pack 100 according to a first exemplary embodiment of the present disclosure is shown in FIG. 1 to FIG. 4B. In these drawings, FIG. 1 is a schematic perspective view showing battery pack 100 according to the first exemplary embodiment, FIG. 2 is a schematic exploded perspective view of battery pack 100, FIG. 3 is an enlarged schematic view of a laser welded region, and FIGS. 4A and 4B are respectively schematic plan views showing a wiring pattern.

### (Battery Pack 100)

Battery pack 100 shown in FIG. 1 or FIG. 2 includes battery block 10 in which a plurality of secondary battery cells 1 is arranged at fixed positions by battery holders 12, circuit board 2 connected to secondary battery cells 1 of battery block 10, and outer covering case 15 that houses circuit board 2 and battery block 10. Outer covering case 15 includes output terminals 16 on the surface thereof. Circuit board 2 is electrically connected to lead plates 3 by laser welding. Lead plates 3 electrically connected to circuit board 2 connects circuit board 2 to secondary battery cells 1, output terminals 16, and the like.

### (Circuit Board 2)

Battery block 10 shown in FIG. 1 includes circuit board 2 on a surface (upper surface in the drawing) of a plastic battery holder 12 in which secondary battery cells 1 are arranged at fixed positions. On circuit board 2, for example, electronic circuits are mounted. Examples of the electronic circuits include a current detection circuit for detecting a charging and discharging current, a circuit for detecting and calculating the full charge and remaining capacity of secondary battery cells 1 from battery information such as voltages and temperatures of secondary battery cells 1, a control circuit for controlling the charging and discharging of secondary battery cells 1, or a protection circuit for monitoring whether or not the battery is normal. Circuit board 2 in the drawing is formed in a rectangular shape, but circuit board 2 can be formed in shapes other than a rectangular shape. Circuit board 2 is a multilayer board in which a plurality of insulating layers 21 is laminated, and insulating layers 21 are preferably made of resin such as glass epoxy. Note here that the present disclosure does not limit the type, configuration, manufacturing method, process, and the like, of an insulating layer.

Circuit board 2 as a multilayer board includes a plurality of insulating layers 21 and wiring patterns 22 (wiring layers) laminated alternately. The plurality of insulating layers 21 can be obtained by, for example, alternately laminating base material layers and prepreg layers so that the base material layers are sandwiched between the prepreg layers. Furthermore, a resist layer or the like to protect the surface can also be provided. Circuit board 2 shown in the enlarged sectional view of FIG. 3 is a multilayer board including laminated three insulating layers 21 in which second insulating layer 21B is laminated on the back surface of first insulating layer 21A, and third insulating layer 21C is laminated on the back surface of second insulating layer 21B. When a multiple-board includes laminated three insulating layers 21, second insulating layer 21B in the middle is made of a base material layer, and first insulating layer 21A and third insulating layer 21C sandwiching second insulating layer 21B from both upper and lower surface side can be made of prepreg layers. Circuit board 2 shown in the drawing includes three layers, first insulating layer 21A, second insulating layer 21B, and third insulating layer 21C, laminated in this order from the surface provided with lead connection part 31. Circuit board 2 shown in FIG. 3 includes copper foil 23 of wiring pattern 22, which is a wiring layer, provided between insulating layers 21. Wiring patterns 22 provided between the upper and lower insulating layers 21 is sandwiched and attached between the upper and lower insulating layers 21 and adheres to the surfaces (upper and lower surfaces) of upper and lower insulating layers 21. Wiring patterns 22 are arranged on the surfaces including the front and back (upper and lower surfaces) of insulating layers 21. Wiring pattern 22 provided between insulating layers 21 is sandwiched and attached between the lower surface of upper insulating layers 21 and the upper surface of the lower insulating layers 21 and adheres thereto. Circuit board 2 in FIG. 3 shows copper foils 23 of three layers of wiring patterns 22, that is, wiring pattern 22 (surface wiring pattern 22a) on the surface provided with lead connection part 31, wiring pattern 22 between first insulating layer 21A and second insulating layer 21B, and wiring pattern 22 between second insulating layer 21B and third insulating layer 21C. However, the circuit board as a multilayer board of the present disclosure does not limit the number of insulating layers and wiring patterns. For example, the insulating layer can be three or more layers, and the wiring patterns (copper foil) can be, for example, multilayer wiring patterns of, for example, four layers, six layers, eight layers, or more layers can be laminated.

Circuit board 2 as a multilayer board is produced by laminating a plurality of insulating layers 21 in an adhesion state. Circuit board 2 includes wiring patterns 22 of copper foil 23 on the upper and lower surfaces and between laminated insulating layers 21. Copper foil 23 prevents a surface from coming into contact with the air by insulating layer 21 that adheres to the surface, and suppresses oxidation of the surface of copper foil 23. The surface of copper foil 23 that is not oxidized is highly reflective with respect to a laser beam, and copper foil 23 is prevented from being melted by the laser beam. Battery pack 100 of the present disclosure effectively uses the unique physical property that the copper surface efficiently reflects a laser beam, thereby preventing the disadvantage that a laser beam melts and penetrates circuit board 2. In particular, copper foil 23 provided as wiring pattern 22 on circuit board 2 is effectively used, copper foil 23 reflects a laser beam, thus preventing the disadvantage that laser beam melts and penetrates circuit board 2. The structure of effectively using copper foil 23 of circuit board 2 to prevent the disadvantage that a laser beam penetrates circuit board 2 is effective in preventing oxidation of the surface of copper foil 23 by insulating layer 21 adhering to the surface of copper foil 23 more effectively, and stably maintaining high reflectivity with respect to the laser beam by the surface of copper foil 23. Therefore, the structure of using copper foil 23 already provided as wiring pattern 22 on circuit board 2 also as a member for preventing the disadvantage that the laser beam penetrates circuit board 2 can eliminate the damage to circuit board 2 by the laser beam with a simple structure that effectively uses a part of copper foil 23 of wiring pattern 22 without providing a special-purpose member, for example, a separate member to be sandwiched between insulating layers 21 to prevent the disadvantage by the laser beam. In addition, the structure can prevent the disadvantage by the laser beam, and can reliably and stably electrically connect the circuit board and the lead plate by laser welding.

Circuit board 2 shown in the enlarged sectional view of FIG. 3 has lead connection part 31 provided on the surface of first insulating layer 21A. Lead connection part 31 shown in this drawing is electrically connected to copper foil 23 (surface copper foil 23a) of wiring pattern 22 (surface wiring pattern 22a) provided on the surface of circuit board 2 by soldering metal plate 32. Metal plate 32 is thicker than copper foil 23. The thickness of copper foil 23 can be, for example, 0.01 mm or more and 0.06 mm or less, and the thickness of metal plate 32 can be, for example, 13 times or more, and preferably 15 times or more than that of the copper foil, and the thickness is, for example, about 1 mm. The lead plate can be stably electrically connected to the circuit board via a metal plate thicker than the copper foil. For example, an aluminum plate with a surface plated with nickel can be used as metal plate 32 so that lead plate 3 can be stably laser-welded and the electrical resistance can be reduced. However, the metal plate can also be other metal plates such as iron with a surface plated with nickel, or the entire plate can be a nickel plate.

Circuit board 2 shown in the enlarged sectional view of FIG. 3 includes reflective copper foil 24 that reflects a laser beam as a part of wiring pattern 22 between first insulating layer 21A and second insulating layer 21B, and in a position facing the welded region where lead plate 3 is laser welded to lead connection part 31. In reflective copper foil 24, laser reflecting surface 24a (in the drawing, the upper surface of reflective copper foil 24) adheres to a back surface of first insulating layer 21A laminated above thereon, and oxidation of the surface is prevented. Reflective copper foil 24 whose surface is kept unoxidized is highly reflective with respect to a laser beam and can efficiently reflect the laser beam without being melted, thus preventing the laser beam from penetrating circuit board 2. Laser welding of lead plate 3 uses a laser beam that is reflected by reflective copper foil 24 and that can avoid the disadvantage that the laser beam penetrates circuit board 2. For example, a YAG laser is used for laser welding of lead plate 3, but the reflectivity of the YAG laser on the unoxidized copper surface is high as about 90%, and copper absorbs only about 10% of the energy of the laser beam, and the energy of absorption is about ⅓ of that by nickel. The present disclosure effectively utilizes the unique physical property of circuit board 2 provided with wiring pattern 22 of copper foil 23, that is, the unique physical property of copper foil 23 provided on a printed board, that is, the unique physical properties of copper foil 23 that do not melt with the laser beam, to prevent the disadvantage caused when the laser beam penetrates circuit board 2.

Circuit board 2 includes reflective copper foil 24 in a position that is at a back surface of first insulating layer 21A including lead connection part 31 on the surface thereof, and in a position facing a welded region made by welding lead connection part 31 and lead plate 3. Reflective copper foil 24 is arranged on the back surface of first insulating layer 21A, that is, the back surface of first insulating layer 21A or a surface including the back surface of insulating layer 21 that is a lower layer than first insulating layer 21A (upper surface or lower surface). Reflective copper foil 24 is arranged to adhere to the back surface of insulating layer 21. Reflective copper foil 24 is preferably disposed near a surface of any one of insulating layers 21 arranged on the surface of lead connection part 31, and on the back surface of insulating layer 21 that is a shallow place. The laser beam is reflected by reflective copper foil 24, and the laser beam does not proceed deeper than reflective copper foil 24. This is because when reflective copper foil 24 is disposed on the back surface of insulating layer 21 at a shallow position, the depth to which the laser beam penetrates can be kept shallow, the range in which an interlayer short circuit occurs can be limited, thereby preventing the disadvantages caused by the laser beam penetrating circuit board 2. Circuit board 2 in FIG. 3 includes reflective copper foil 24 on the back side (lower surface side) of first insulating layer 21A, and a laser beam can be reflected by laser reflecting surface 24a of reflective copper foil 24 and can be prevented from traveling deeper than first insulating layer 21A and penetrating it.

As shown in FIG. 3, first insulating layer 21A is provided with reflective copper foil 24 in wiring pattern 22 of copper foil 23 on the back surface. As shown in FIG. 4B, reflective copper foil 24 is floating island 25 that is not connected to copper foil 23 of other wiring patterns 22, like an island that exists independently away from a land. FIG. 4A shows copper foil 23 of wiring pattern 22 on the surface (a surface of first insulating layer 21A) of circuit board 2 to which lead connection part 31 is connected. FIG. 4B shows that reflective copper foil 24 of wiring pattern 22 on the back surface of first insulating layer 21A is floating island 25, and non-connected part 26 is formed around floating island 25. Non-connected part 26 separates floating island 25 from copper foil 23 of other wiring patterns 22 to be in a non-connected state. Reflective copper foil 24 of floating island 25 ensures that it is not connected to copper foil 23 of other wiring patterns 22 on the same layer. Reflective copper foil 24 of floating island 25 can prevent disadvantage caused when metal of lead connection part 31 or copper foil 23 on the surface melt during laser welding of lead plate 3, and the molten metal penetrating insulates layer 21 and is electrically connected to reflective copper foil 24. Reflective copper foil 24 prevents itself from being melted by an irradiated laser beam, but does not prevent a laser beam from melting and penetrating first insulating layer 21A. The laser beam penetrating first insulating layer 21A melts the metal of lead connection part 31, or melts wiring pattern 22 with the heat, and allow the molten metal to flow down a through hole and may be electrically connected to reflective copper foil 24 provided on the back surface.

The disadvantage caused when molten metal such as lead connection part 31 and the like is connected to reflective copper foil 24 can be solved by forming reflective copper foil 24 as floating island 25. In the multilayer board, copper foils 23 are disposed in the optimal wiring pattern 22 on the front and back surfaces of first insulating layer 21A, but wiring pattern 22 of copper foil 23 is not disposed in a pattern that electrically connects lead connection part 31 and reflective copper foil 24. Even if the molten metal that penetrates insulating layer 21 electrically connects lead connection part 31 and reflective copper foil 24, the electrical connection by the molten metal cannot be a stable electrical connection as by a through hole that penetrates insulating layer 21 of the multilayer board, and the circuit configuration is not a circuit configuration in which wiring patterns 22 on both surfaces are electrically connected at the position where the molten metal penetrates insulating layer 21. Therefore, when a laser beam electrically connects lead connection part 31 and reflective copper foil 24, circuit board 2 cannot operate normally. With a circuit configuration in which reflective copper foil 24 provided on the back surface of first insulating layer 21A is wiring pattern 22 connected to a ground line, and lead connection part 31 is connected to a positive power supply line, a disadvantage that the molten metal short-circuits output terminal 16 to the ground line. In reflective copper foil 24 of floating island 25, when it is assumed that lead connection part 31 is electrically connected to reflective copper foil 24 by the molten metal, reflective copper foil 24 of floating island 25 does not connect lead connection part 31 to another circuit, and normal operation of circuit board 2 is secured.

Reflective copper foil 24 includes laser reflection surface 24a that reflects a laser beam. Laser reflection surface 24a is in a size and shape capable of covering at least a range to which the laser beam hits, considering the size of lead connection part 31 and positional displacement of irradiation of the laser beam. Reflective copper foil 24 of floating island 25 includes laser reflection surface 24a, and non-connected part 26 that is not connected to copper foil 23 of other wiring patterns 22 is formed around floating island 25. The width of non-connected part 26 is a width that ensures that reflective copper foil 24 is not connected to copper foil 23 of other wiring patterns 22 on the same layer, even if lead connection part 31 is electrically connected to reflective copper foil 24 by molten metal by laser beam. Therefore, reflective copper foil 24 of floating island 25 can reliably avoid the disadvantage of the laser beam penetrating circuit board 2. Copper foil 23 of wiring pattern 22 disposed on a surface of first insulating layer 21A that is a surface of circuit board 2 connected to lead connection part 31 is defined as the surface copper foil 23a of surface wiring pattern 22a. A part of surface copper foil 23a, including a region directly below a welded region in the laminated direction of a plurality of insulating layers 21 and including a part connected to lead connection part 31 or a part arranged directly above reflective copper foil 24, is defined as connection copper foil 23b. Connection copper foil 23b can be the same as or different from reflective copper foil 24 in shape, size, and area. For example, connection copper foil 23b can be smaller in area than reflective copper foil 24, or can be in a different shape from reflective copper foil 24. Connection copper foil 23b can be in a shape that removes surface copper foil 23a of surface wiring pattern 22a directly below the welded region where lead connection part 31 and lead plate 3 are welded by a laser beam. Connection copper foil 23b in FIG. 4A includes copper foil removed region 23c that does not include surface copper foil 23a of surface wiring pattern 22a directly below the welded region. Connection copper foil 23b is smaller than reflective copper foil 24, and in particular includes copper foil removed region 23c that does not include surface copper foil 23a of surface wiring pattern 22a directly below the welded region, which can prevent or reduce melting of surface copper foil 23a of surface wiring pattern 22a by the laser beam or its heat, and flowing of melted surface copper foil 23a down into a through hole. Thereby, electrical connection with reflective copper foil 24 provided on the back surface of insulating layer 21 can be avoided or suppressed.

Connection copper foil 23b is formed in a shape, size, and area that can stably connect lead connection part 31, so that lead plate 3 can be stably electrically connected to circuit board 2 via lead connection part 31. Connection copper foil 23b can be provided, for example, in a shape that surrounds the periphery except for the region directly below the welded region, or in a shape such as a straight line, a curved line, or a plane that partially surrounds the periphery. Connection copper foil 23b of FIG. 4A is two parallel straight lines extending in the left-right direction except for the region directly below the welding area. Connection copper foil 23b can stably electrically connect lead plate 3 to circuit board 2 via lead connection part 31 while preventing surface copper foil 23a from melting and flowing down into the through hole.

### Second and Third Exemplary Embodiments

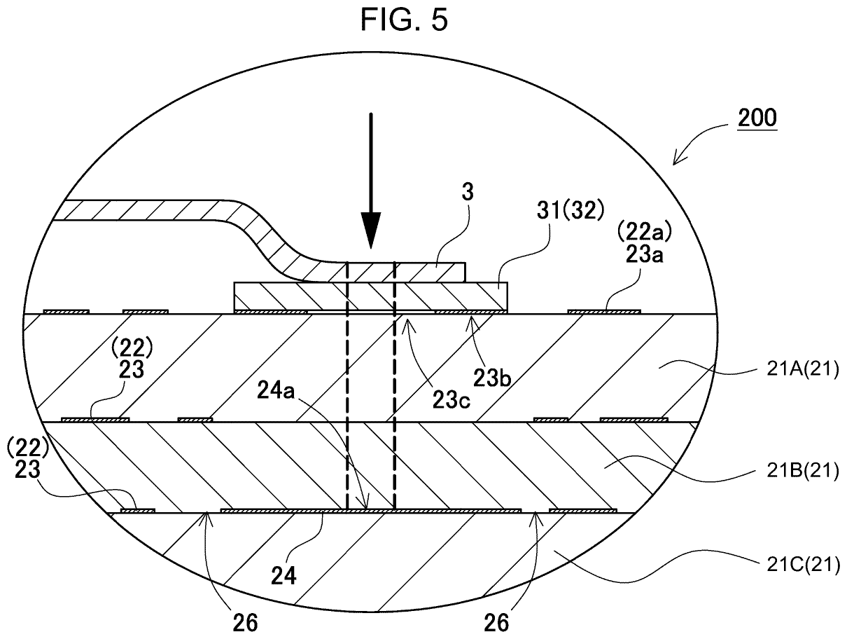

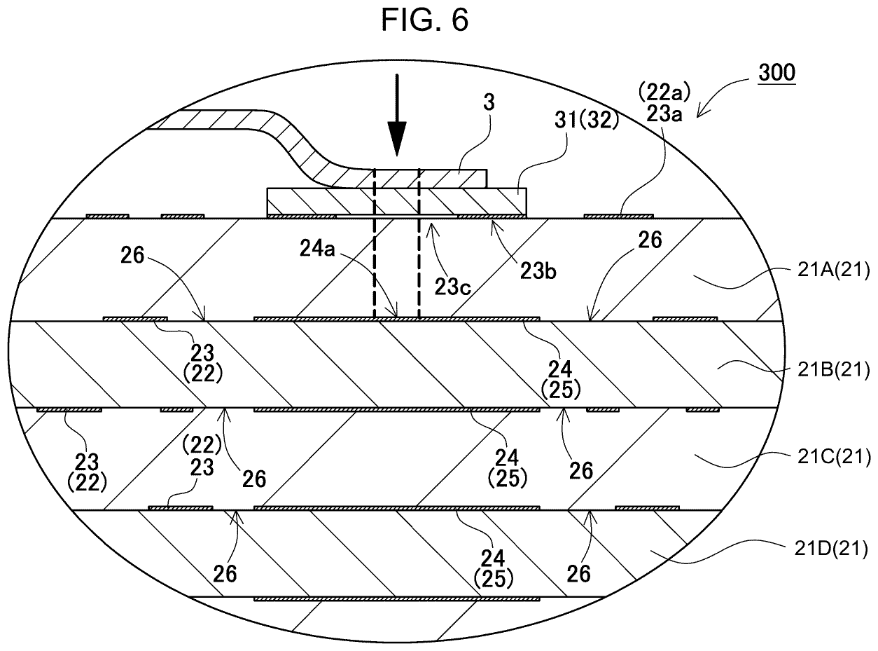

Battery packs 200 and 300 according to the second and third exemplary embodiments of the present disclosure are shown in FIG. 5 and FIG. 6, respectively. Circuit board 2 of battery pack 100 shown in FIG. 3 includes reflective copper foil 24 on the back surface of first insulating layer 21A, that is, on wiring pattern 22 between first insulating layer 21A and second insulating layer 21B, but reflective copper foil 24 can be provided on wiring pattern 22 on the back surface of insulating layer 21 below first insulating layer 21A. In FIG. 5, reflective copper foil 24 is provided on the back surface of second insulating layer 21B. That is, in FIG. 5, reflective copper foil 24 is provided on wiring pattern 22 between second insulating layer 21B and third insulating layer 21C. Furthermore, although not shown, the reflective copper foil can be provided on the back surface of any one of the insulating layers below the first insulating layer, for example, on the back surface of the third insulating layer, or on an insulating layer arranged below that. By providing reflective copper foil 24 on the back surface of any of insulating layers 21 below first insulating layer 21A, the degree of freedom in designing wiring pattern 22 can be increased while the disadvantage that the laser beam penetrates circuit board 2 is avoided. Furthermore, the depth of insulating layer 21 through which the laser beam penetrates can be adjusted. As described above, when reflective copper foil 24 is provided on the back surface of any of insulating layers 21 below first insulating layer 21A, when the intermediate wiring pattern provided on the back surface of the insulating layer disposed between lead connection part 31 and reflective copper foil 24 in the thickness direction includes a copper foil removed region that removes copper foil 23 of wiring pattern 22 directly below the welded region in which lead connection part 31 and lead plate 3 are welded by the laser beam, melting of copper foil 23 of intermediate wiring pattern 22 by the laser beam or heat thereof used when welding lead plate 3 to lead connection part 31. This can avoid or suppress melting of copper foil 23 of intermediate wiring pattern 22 and penetrating of the melted copper foil 23 through insulating layer 21 and being electrically connected to reflective copper foil 24. Note here that when intermediate wiring pattern 22 includes a copper foil removed region as described above, it is possible to avoid or suppress electrically connecting of copper foil 23 of intermediate wiring pattern 22, so that it is preferable that connecting copper foil 23b is provided on the entire back surface of metal plate 32 without providing copper foil removed region 23c in surface copper foil 23a of surface wiring pattern 22a.

Circuit board 2 of battery pack 300 can include a plurality of reflective copper foils 24. The plurality of reflective copper foils 24 is arranged in positions facing the welded region formed by welding lead connection part 31 and lead plate 3 by irradiation with a laser beam, and each reflective copper foil 24 can be disposed between the plurality of insulating layers 21. Even when the plurality of reflective copper foils 24 is provided, it is preferable to dispose reflective copper foil 24 that is the closest to the surface of the multilayer board on the back surface of the back surface insulating layer 21 at a shallow part (for example, the back surface of first insulating layer 21A). This is because the penetration depth of the laser beam can be kept shallow, and a plurality of reflective copper foils 24 can be provided below the shallowest reflective copper foil 24. When the plurality of reflective copper foils 24 is provided, the shapes and sizes of reflective copper foils 24 can be the same or different.

All or any of the plurality of reflective copper foils 24 can be formed into floating islands 25. FIG. 6 shows that four layers of reflective copper foils 24 are laminated. In this drawing, reflective copper foils 24 are provided on the back surface of first insulating layer 21A, the back surface of second insulating layer 21B, the back surface of third insulating layer 21C, and the back surface of fourth insulating layer 21D. Furthermore, in FIG. 6, all of reflective copper foils 24 are as floating islands 25. In this way, by providing the plurality of reflective copper foils 24 and forming them into floating islands 25, the disadvantage that the laser beam penetrates circuit board 2 can be prevented more reliably, so that the safety of the battery pack can be improved. Moreover, as described above, circuit board 2 of the multilayer board can effectively utilize a part of already existing wiring pattern 22. In both cases of arranging reflective copper foil 24 and forming as floating island 25, it is advantageous that by simply changing the shape of a part of already existing wiring pattern 22 in circuit board 2, it is possible to reliably prevent the disadvantage that a laser beam penetrates circuit board 2 without arranging any other special-purpose components and without increasing costs, and to secure a further improvement in safety. In particular, with increasing demand for higher density and thinner circuit boards, the significance of reliably preventing the disadvantage that the laser beam penetrates the circuit board during laser welding and securing safety becomes more important in multilayer boards including 10 or more layers, several tens of layers, 100 layers, and the like.

### INDUSTRIAL APPLICABILITY

The battery pack disclosed in this disclosure can be suitably used as a battery pack that can reliably and stably connect electrodes of a circuit board and a lead plate by avoiding the disadvantage that a laser beam of a laser welding penetrates the circuit board.

### REFERENCE SIGNS LIST

100, 200, 300, 900: Battery pack
1: Secondary battery cell
2: Circuit board
3: Lead plate
10: Battery block
12: Battery holder
15: Outer covering case
16: Output terminal
21: Insulating layer
21A: First insulating layer
21B: Second insulating layer
21C: Third insulating layer
21D: Fourth insulating layer
22: Wiring pattern
22a: Surface wiring pattern
23: Copper foil
23a: Surface copper foil
23b: Connection copper foil
23c: Copper foil removed region
24: Reflective copper foil
24a: Laser reflection surface
25: Floating island
26: Non-connected part
31: Lead connection part
32: Metal plate

1. A battery pack comprising:
a battery block including a plurality of battery cells at predetermined positions,
a circuit board connected to the plurality of battery cells of the battery block, and
a lead plate connected to a lead connection part provided on a front surface of the circuit board,
the circuit board
being a multilayer board including a plurality of insulating layers including a first insulating layer and a wiring pattern, laminated in each of a plurality of layers,
the circuit board including a reflective copper foil reflecting a laser beam,
the reflective copper foil being on a back surface of the first insulating layer, the first insulating layer including a front surface to which the lead connection part is arranged, and
the reflective copper foil being in a position facing a welded region in which the lead connection part and the lead plate are welded to each other,
the reflective copper foil including a laser reflection surface reflecting a laser beam on a surface facing a back surface of any one insulating layer of the plurality of insulating layers,
the laser reflection surface adhering to a back surface of the any one insulating layer of the plurality of insulating layers of a laminated structure, and
the laser reflection surface being covered with the any one insulating layer.

2. The battery pack according to claim 1, wherein
the plurality of insulating layers of the circuit board includes,
a second insulating layer laminated on the back surface of the first insulating layer,
the reflective copper foil is placed between the first insulating layer and the second insulating layer.

3. The battery pack according to claim 1, wherein
the reflective copper foil is
a floating island that is not connected to a copper foil of the wiring pattern.

4. The battery pack according to claim 1, wherein
the circuit board includes one or a plurality of reflective copper foils, the reflective copper foil being one of the one or the plurality of reflective copper foils,
the one or the plurality of reflective copper foils is a floating island that is not connected to a copper foil of the wiring pattern.

5. The battery pack according to claim 1, wherein
the lead connection part is a metal plate fixed to electrically connected to
a copper foil of a wiring pattern provided on a front surface of the first insulating layer of the circuit board.

6. The battery pack according to claim 5, wherein
the lead connection part is
a metal plate soldered to the copper foil of the wiring pattern.

7. The battery pack according to claim 5, comprising
a copper foil removed region that does not include the copper foil of the wiring pattern directly below a welded region of the metal plate on a front surface of the circuit board in a laminated direction of the plurality of insulating layers.

8. The battery pack according to claim 5, wherein
the metal plate of the lead connection part is
a metal plate that is thicker than the copper foil of the wiring pattern.

9. The battery pack according to claim 5, wherein,
the metal plate of the lead connection part is
a metal plate including a front surface plated with nickel.

10. The battery pack according to claim 1, wherein
the battery block comprises
a battery holder including the plurality of battery cells at fixed positions,
the battery holder includes the circuit board at a fixed position,
the lead plate includes
a first end laser-welded to the lead connection part, and
a second end connected to a corresponding battery cell among the plurality of battery cells.

11. The battery pack according to claim 1, comprising:
an outer covering case hosing the circuit board and the battery block,
the outer covering case including an output terminal,
the lead plate including
a first end laser-welded to the lead connection part, and
a second end connected to the output terminal.
